(19) United States
(12) Patent Application Publication
(10) Pub. No.: US 2026/0353688 A1
(43) Pub. Date: Nov. 5, 2026

(54) SEMICONDUCTOR DEVICE STRUCTURE WITH GATE STACK

(71) Applicant: Taiwan Semiconductor Manufacturing Company, Ltd., Hsinchu (TW)

(72) Inventors: I-Han HUANG, New Taipei City (TW); Chu-Yuan HSU, Taichung City (TW); Jia-Chuan YOU, Taoyuan City (TW); Chia-Hao CHANG, Hsinchu City (TW); Kuo-Cheng CHIANG, Zhubei City (TW)

(21) Appl. No.: 19/742,426

(22) Filed: Jul. 15, 2026

Related U.S. Application Data
(63) Continuation of application No. 18/411,226, filed on Jan. 12, 2024.

(51) Int. Cl. H10D 30/01; H10D 30/67; H10D 62/10; H10D 64/01; H10D 64/23

(52) U.S. Cl. CPC H10D 30/014; H10D 30/6735; H10D 30/6757; H10D 62/121; H10D 64/01; H10D 64/015; H10D 64/017; H10D 64/018; H10D 64/258

(57) ABSTRACT

A semiconductor device structure is provided. The semiconductor device structure includes an epitaxial structure and a channel structure beside the epitaxial structure. The semiconductor device structure also includes a metal gate stack over the channel structure. The metal gate stack has a gate dielectric layer and a gate electrode, and topmost surfaces of the gate dielectric layer and the gate electrode are located at different height levels. The semiconductor device structure further includes a protective structure over the metal gate stack and the epitaxial structure. A top of the epitaxial structure is closer to a top of the protective structure than a bottom of the protective structure.

### PRIORITY CLAIM AND CROSS-REFERENCE

This Application is a Continuation of U.S. Application No. 18/411,226, filed on Jan. 12, 2024, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3I are cross-sectional views of various stages of a process for forming a portion of a semiconductor device structure, in accordance with some embodiments.

FIGS. 4A-4L are perspective views of various stages of a process for forming a portion of a semiconductor device structure, in accordance with some embodiments.

FIGS. 4J-1 and 4K-1 are cross-sectional views of various stages of a process for forming a portion of a semiconductor device structure, in accordance with some embodiments.

FIG. 5 is a cross-sectional view of a stage of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using another applicable process.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

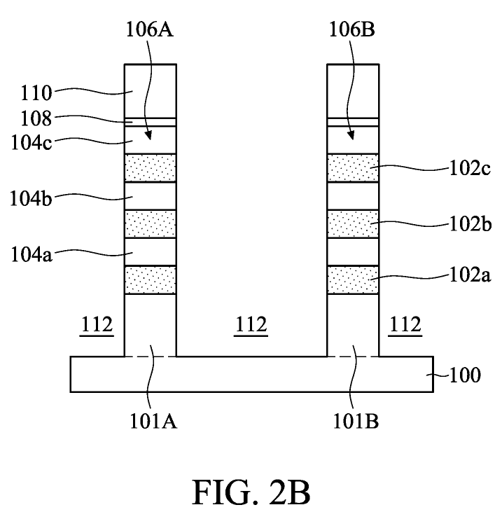

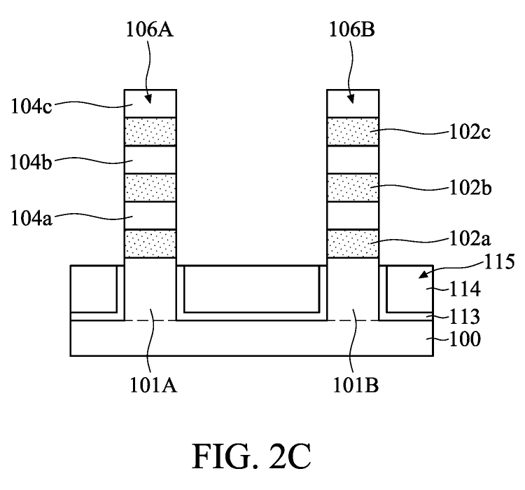

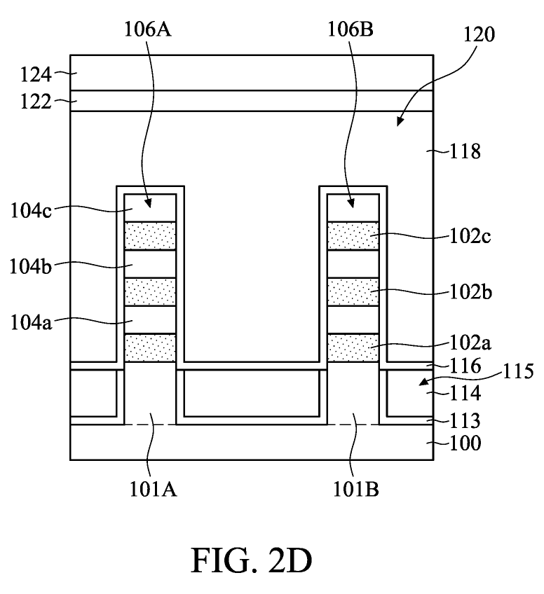

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, another suitable material, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner, as shown in FIG. 2A. In some embodiments, the semiconductor layers 102a-102d and 104a-104d together form a superlattice structure.

In some embodiments, the semiconductor layers 102a-102c function as sacrificial layers that will be removed in a subsequent process to release the semiconductor layers 104a-104c. The semiconductor layers 104a-104c that are released may function as channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, germanium, another suitable material, or a combination thereof.

In some embodiments, the semiconductor layers 102a-102c are made of or include silicon germanium. In some other embodiments, the semiconductor layers 104a-104c are made of silicon germanium, and the semiconductor layers 102a-102c are made of silicon germanium with different atomic concentration of germanium than that of the semiconductor layers 104a-104c. As a result, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics.

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor layers 102a-102c and 104a-104c is accomplished.

Afterwards, hard mask elements are formed over the semiconductor stack to assist in a subsequent patterning of the semiconductor stack. One or more photolithography processes and one or more etching processes are used to pattern the semiconductor stack into multiple fin structures including fin structures 106A and 106B, as shown in FIG. 2B in accordance with some embodiments.

The fin structures 106A and 106B may be patterned by any suitable method. For example, the fin structures 106A and 106B may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form trenches 112, as shown in FIG. 2B. Each of the fin structures 106A and 106B may include portions of the semiconductor layers 102a-102c and 104a-104c and semiconductor fins 101A and 101B. The semiconductor substrate 100 may also be partially removed during the etching process that forms the fin structures 106A and 106B. Protruding portions of the semiconductor substrate 100 that remain form the semiconductor fins 101A and 101B. Each of the semiconductor fins 101A and 101B may have a height that is within a range from about 35 nm to about 55 nm.

Each of the hard mask elements may include a first mask layer 108 and a second mask layer 110. The first mask layer 108 and the second mask layer 110 may be made of different materials. In some embodiments, the first mask layer 108 is made of a material that has good adhesion to the semiconductor layer 104c. The first mask layer 108 may be made of silicon oxide, germanium oxide, silicon germanium oxide, another suitable material, or a combination thereof. The second layer 110 may be made of silicon nitride, silicon oxynitride, silicon carbide, another suitable material, or a combination thereof.

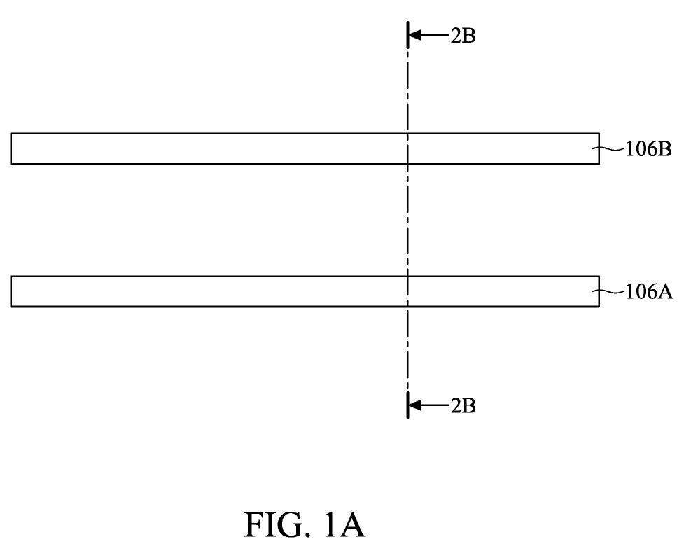

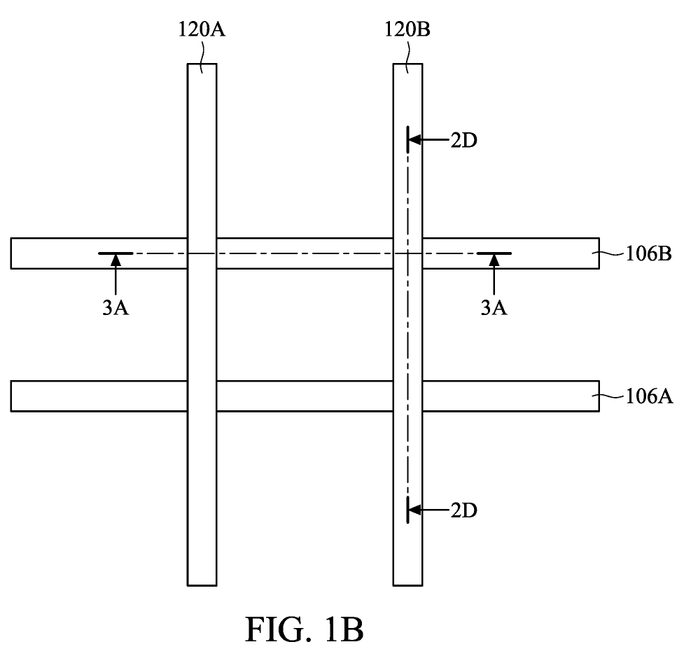

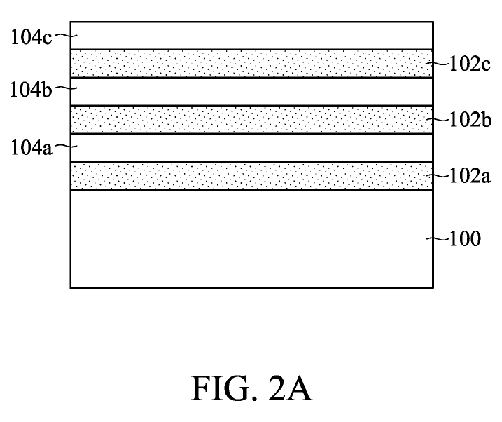

FIGS. 1A-1B are top views of various stages of a process for forming a portion of a semiconductor device structure, in accordance with some embodiments. In some embodiments, the fin structures 106A and 106B are oriented lengthwise. In some embodiments, the longitudinal extending directions of the fin structures 106A and 106B are substantially parallel to each other, as shown in FIG. 1A. In some embodiments, FIG. 2B is a cross-sectional view of the structure taken along the line 2B-2B in FIG. 1A.

As shown in FIG. 2C, an isolation structure 115 is formed to surround lower portions of the fin structures 106A and 106B, in accordance with some embodiments. In some embodiments, the isolation structure 115 includes a dielectric filling 114 and a liner layer 113 that is adjacent to the semiconductor fins 101A and 101B. In some embodiments, the semiconductor fins 101A and 101B protrude from the top surface of the isolation structure 115.

In some embodiments, one or more dielectric layers are deposited over the fin structures 106A and 106B and the semiconductor substrate 100 to overfill the trenches 112. The dielectric layers may be made of silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof. The liner layer 113 may be made of or include silicon nitride, silicon oxynitride, silicon carbide, silicon oxycarbide, another suitable material, or a combination thereof. The dielectric layers and the liner layer 113 may be deposited using a flowable chemical vapor deposition (FCVD) process, an atomic layer deposition (ALD) process, a chemical vapor deposition (CVD) process, another applicable process, or a combination thereof.

Afterwards, a planarization process is used to partially remove the dielectric layers and the liner layer 113. The hard mask elements (including the first mask layer 108 and the second mask layer 110) may also function as stop layers of the planarization process. The planarization process may include a chemical mechanical polishing (CMP) process, a grinding process, a dry polishing process, an etching process, another applicable process, or a combination thereof.

Afterwards, one or more etching back processes are used to partially remove the dielectric layers and the liner layer 113. As a result, the remaining portion of the dielectric layers forms the dielectric filling 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level. In some embodiments, the topmost surface of the isolation structure 115 is below the bottommost surface of the semiconductor layer 102a which functions as a sacrificial layer, as shown in FIG. 2C.

Afterwards, the remaining portions of the hard mask elements (including the first mask layer 108 and the second mask layer 110) are removed. Alternatively, in some other embodiments, the hard mask elements are removed or consumed during the planarization process and/or the etching back process that forms the isolation structure 115.

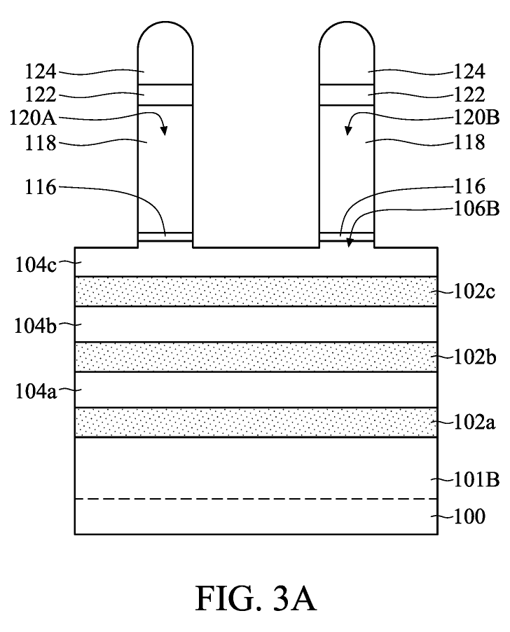

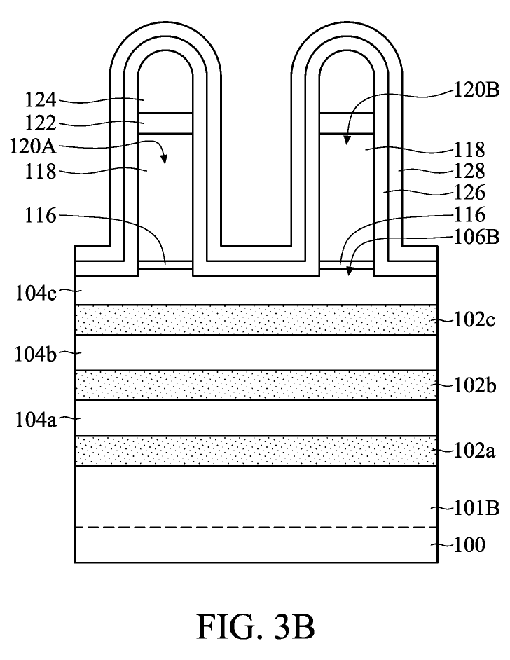

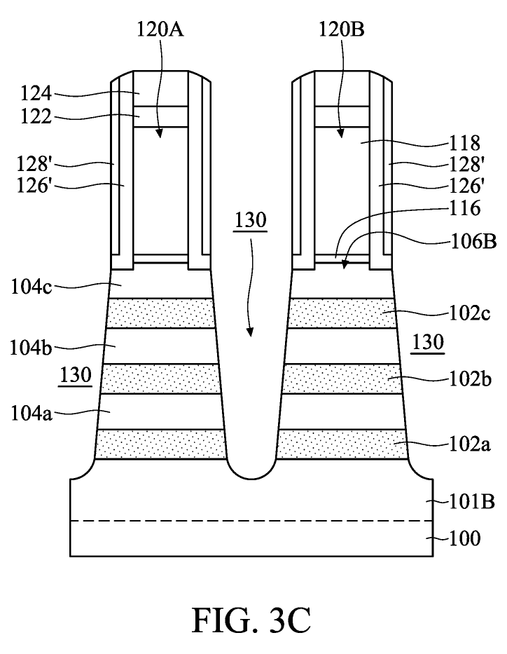

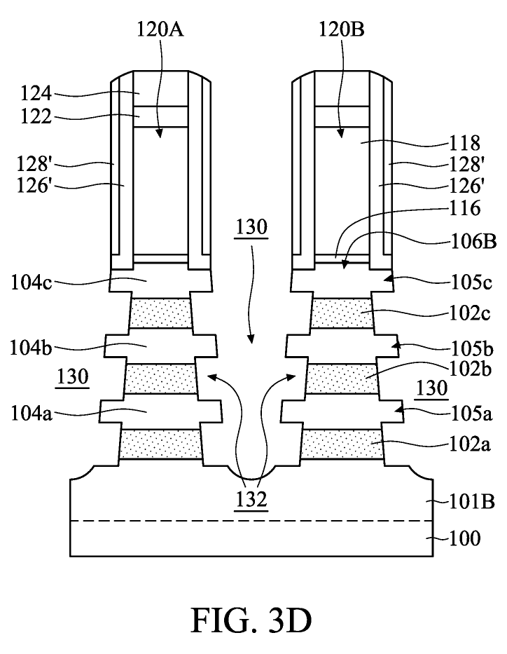

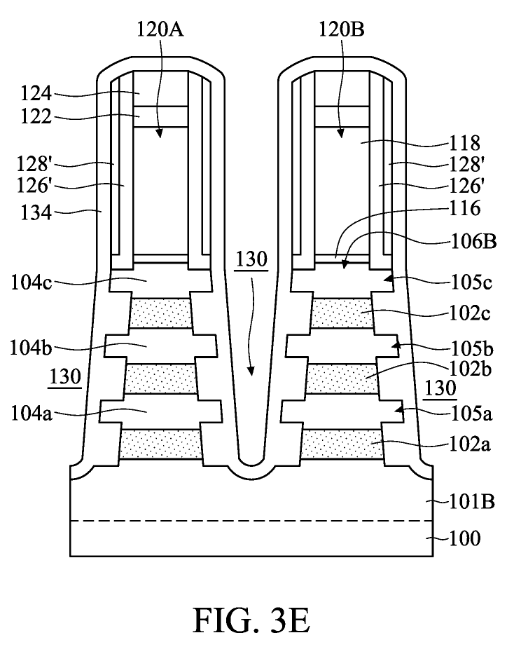

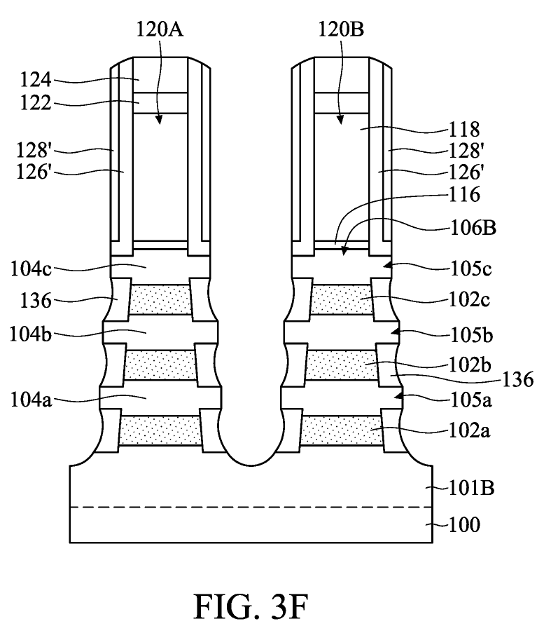

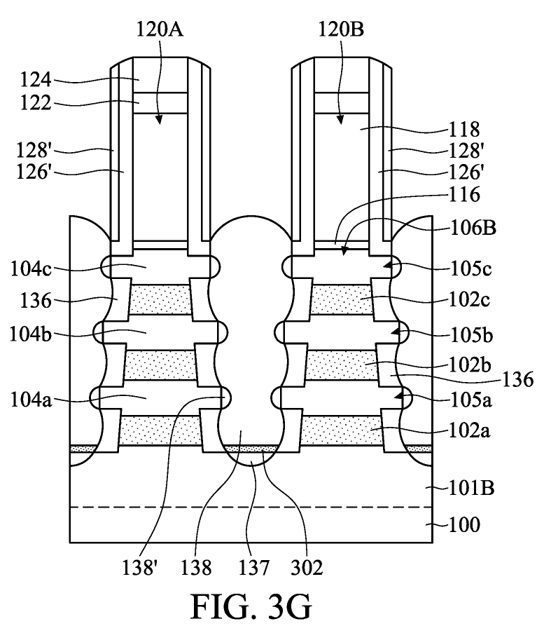

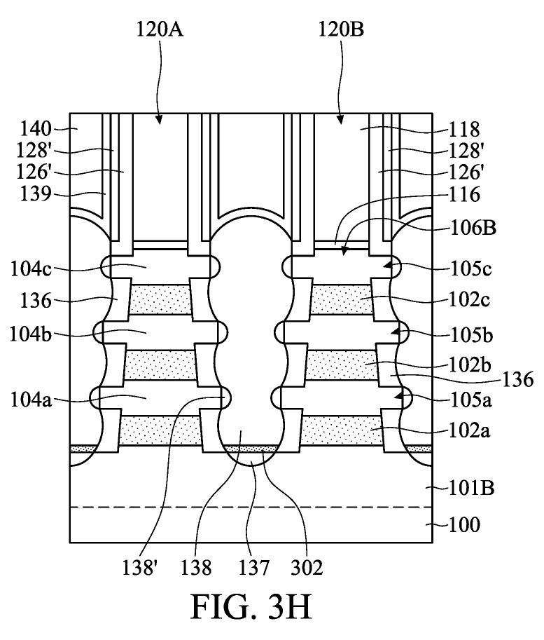

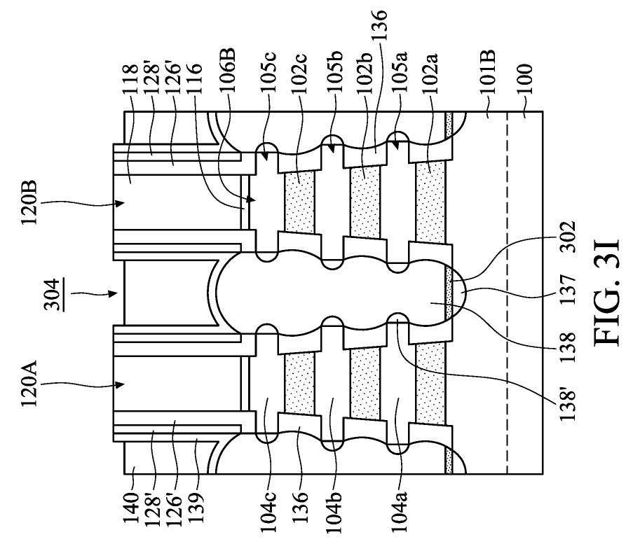

Afterwards, dummy gate stacks 120A and 120B are formed to extend across the fin structures 106A and 106B, as shown in FIG. 1B in accordance with some embodiments. In some embodiments, FIG. 2D is a cross-sectional view of the structure taken along the line 2D-2D in FIG. 1B. FIGS. 3A-3I are cross-sectional views of various stages of a process for forming a portion of a semiconductor device structure, in accordance with some embodiments. In some embodiments, FIG. 3A is a cross-sectional view of the structure taken along the line 3A-3A in FIG. 1B.

As shown in FIGS. 1B, 2D, and 3A,the dummy gate stacks 120A and 120B are formed to partially cover and to extend across the fin structures 106A and 106B, in accordance with some embodiments. In some embodiments, the dummy gate stacks 120A and 120B are wrapped around portions of the fin structures 106A and 106B. As shown in FIG. 1B, other portions of the fin structures 106A and 106B are exposed without being covered by the dummy gate stacks 120A and 120B.

As shown in FIGS. 2D and 3A, each of the dummy gate stacks 120A and 120B includes a dummy gate dielectric layer 116 and a dummy gate electrode 118. The dummy gate dielectric layers 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, another applicable process, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements including mask layers 122 and 124 are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B that include the dummy gate dielectric layers 116 and the dummy gate electrodes 118.

As shown in FIG. 3B, spacer layers 126 and 128 are afterwards deposited over the dummy gate stacks 120A and 120B and the fin structure 106B, in accordance with some embodiments. The spacer layers 126 and 128 extend along the tops and sidewalls of the dummy gate stacks 120A and 120B, as shown in FIG. 3B. The spacer layers 126 and 128 also extend along the top of the fin structure 106B, as shown in FIG. 3B.

In some embodiments, the spacer layers 126 and 128 are made of different materials. In some other embodiments, the spacer layers 126 and 128 are made of the same material. The spacer layers 126 and 128 may be made of or include silicon nitride, silicon carbide, silicon oxycarbide, carbon-containing silicon oxynitride, silicon oxide, another suitable material, or a combination thereof. In some embodiments, each of the spacer layers 126 and 128 is a single layer. In some other embodiments, one or both of the spacer layers 126 and 128 include multiple sub-layers. Some of the sub-layers may be made of different materials. Some of the sub-layers may be made of similar materials with different compositions. For example, one of the sub-layers may have a greater atomic concentration of carbon than other sub-layers. The spacer layers 126 and 128 may be sequentially deposited using a CVD process, an ALD process, a physical vapor deposition (PVD) process, another applicable process, or a combination thereof.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form gate spacers 126’ and 128’, respectively. The gate spacers 126’ and 128’ extend along the sidewalls of the dummy gate stacks 120A and 120B, as shown in FIG. 3C. The thickness of the gate spacers 126’ and 128’ may be within a range from about 4 nm to about 6 nm.

Afterwards, the fin structures 106A and 106B are partially removed to form recesses used for containing subsequently formed epitaxial structures. As shown in FIG. 3C, the fin structure 106B is partially removed to form recesses 130, in accordance with some embodiments. The recesses 130 expose the side surfaces of the semiconductor layers 104a-104c on which epitaxial structures (such as source/drain structures) will subsequently be formed. A source/drain structure may refer to a source structure or a drain structure, individually or collectively, depending upon the context.

One or more etching processes may be used to form the recesses 130. In some embodiments, a dry etching process is used to form the recesses 130. Alternatively, a wet etching process may be used to form the recesses 130. In some embodiments, each of the recesses 130 penetrates into the fin structure 106B. In some embodiments, the recesses 130 further extend into the semiconductor fin 101B, as shown in FIG. 3C. In some embodiments, the gate spacers 126’ and 128’ and the recesses 130 are simultaneously formed using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

As shown in FIG. 3D, the semiconductor layers 102a-102c are laterally etched, in accordance with some embodiments. As a result, edges of the semiconductor layers 102a-102c retreat from edges of the semiconductor layers 104a-104c. As shown in FIG. 3D, recesses 132 are formed due to the lateral etching of the semiconductor layers 102a-102c. The recesses 132 may be used to contain inner spacers that will subsequently be formed. The semiconductor layers 102a-102c may be laterally etched using a wet etching process, a dry etching process, or a combination thereof. In some other embodiments, the semiconductor layers 102a-102c are partially oxidized before being laterally etched.

In some embodiment, the semiconductor layers 104a-104c may also be slightly etched during the lateral etching of the semiconductor layers 102a-102c. As a result, edge portions of the semiconductor layers 104a-104c are partially etched and thus shrink to form edge portions 105a-105c, as shown in FIG. 3D. As shown in FIG. 3D, each of the edge portions 105a-105c of the semiconductor layers 104a-104c is thinner than the corresponding inner portion of the semiconductor layers 104a-104c. In some other embodiments, the semiconductor layers 104a-104c are substantially not etched during the lateral etching of the semiconductor layers 102a-102c. As a result, edge portions 105a-105c of the semiconductor layers 104a-104c are substantially not shrunk. In some embodiments, each of the edge portions 105a-105c of the semiconductor layers 104a-104c is substantially as thick as the corresponding inner portion of the semiconductor layers 104a-104c.

As shown in FIG. 3E, an insulating layer 134 is deposited over the structure shown in FIG. 3D, in accordance with some embodiments. The insulating layer 134 covers the dummy gate stacks 120A and 120B and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, another suitable material, or a combination thereof. In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, another applicable process, or a combination thereof.

As shown in FIG. 3F, an etching process is used to partially remove the insulating layer 134, in accordance with some embodiments. The portions of the insulating layer 134 outside of the recesses 132 may be removed. The remaining portions of the insulating layer 134 form inner spacers 136, as shown in FIG. 3F. The etching process may include a dry etching process, a wet etching process, or a combination thereof. Each of the inner spacers 136 may have a thickness that is within a range from about 4 nm to about 6 nm.

The inner spacers 136 cover the edges of the semiconductor layers 102a-102c. The inner spacers 136 may be used to prevent subsequently formed epitaxial structures (which function as source/drain structures, for example) from being damaged during a subsequent process for removing the semiconductor layers 102a-102c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101B originally covered by the insulating layer 134 are exposed by the recesses 130, as shown in FIG. 3F. The edges of the semiconductor layers 104a-104c are exposed by the recesses 130, as shown in FIG. 3F.

As shown in FIG. 3G, semiconductor isolation structures 137 are formed over the bottoms of the recesses 130, in accordance with some embodiments. In some embodiments, the semiconductor isolation structures 137 are epitaxial structures that are undoped. In some embodiments, the semiconductor isolation structures 137 are substantially free of n-type dopants or p-type dopants. The semiconductor isolation structures 137 may help to reduce or prevent current leakage from epitaxial structures that will be formed. The semiconductor isolation structures 137 may provide relative planar surfaces, so as to facilitate the subsequent formation of the epitaxial structures.

The semiconductor isolation structures 137 may be made of or include silicon, silicon germanium, another suitable material, or a combination thereof. The semiconductor isolation structures 137 may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the semiconductor isolation structures 137 involve one or more etching processes that are used to fine-tune the profiles of the semiconductor isolation structures 137.

Afterwards, bottom isolation elements 302 are selectively formed on the semiconductor isolation structures 137, as shown in FIG. 3G in accordance with some embodiments. The bottom isolation elements 302 may prevent leakage current between the semiconductor fin 101B and the epitaxial structures that will be formed on the bottom isolation elements 302. Each of the bottom isolation elements 302 has a thickness that may be within a range from about 2 nm to about 6 nm.

In some embodiments, the bottom isolation elements 302 are made of or include a dielectric material. The dielectric material may include silicon oxide, silicon nitride, carbon-containing silicon nitride, carbon-containing silicon oxynitride, carbon-containing silicon oxide, aluminum oxide, hafnium oxide, another suitable material, or a combination thereof. The formation of the bottom isolation elements 302 may involve one or more deposition processes and one or more patterning processes.

However, embodiments of the disclosure are not limited thereto. Many variations and/or modifications can be made to embodiments of the disclosure. In some other embodiments, the bottom isolation elements 302 are not formed.

As shown in FIG. 3G, epitaxial structures 138 are formed on the bottom isolation elements 302 and the side surfaces of the semiconductor layers 104a-104c, in accordance with some embodiments. In some embodiments, the top surfaces of the epitaxial structures 138 are higher than the top surface of the dummy gate dielectric layer 116, as shown in FIG. 3G. In some other embodiments, the epitaxial structures 138 are substantially as high as the tops of the edge portions 105c.

In some embodiments, the epitaxial structures 138 connect to the semiconductor layers 104a-104c. Each of the semiconductor layers 104a-104c is sandwiched between two of the epitaxial structures 138. In some embodiments, the epitaxial structures 138 have lightly doped portions 138’ adjacent to the semiconductor layers 104a-104c. The dopant concentration of the lightly doped portions 138’ is lower than other portions of the epitaxial structures 138.

In some embodiments, the epitaxial structures 138 are p-type doped regions. The epitaxial structures 138 may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138 are n-type doped regions. The epitaxial structures 138 may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138 are doped in-situ during their epitaxial growth. The initial reaction gas mixture for forming the epitaxial structures 138 contains dopants. In some other embodiments, the epitaxial structures 138 are not doped during the growth of the epitaxial structures 138. Instead, after the formation of the epitaxial structures 138, the epitaxial structures 138 are doped in a subsequent process. In some embodiments, the doping is achieved by using an ion implantation process, a plasma immersion ion implantation process, a gas and/or solid source diffusion process, another applicable process, or a combination thereof. In some embodiments, the epitaxial structures 138 are further exposed to one or more annealing processes to activate the dopants. For example, a rapid thermal annealing process is used.

In some embodiments, some of the epitaxial structures 138 are p-type doped, and the other epitaxial structures 138 are n-type doped. A patterned mask may be used to assist in the respective formation of the epitaxial structures 138 that are p-type doped and the epitaxial structures 138 that are n-type doped.

As shown in FIG. 3H, a contact etch stop layer 139 and a dielectric layer 140 are formed over the epitaxial structures 138 and the dummy gate stacks 120A and 120B, in accordance with some embodiments. The contact etch stop layer 139 may be made of or include silicon nitride, silicon oxynitride, silicon carbide, carbon-containing silicon nitride, carbon-containing silicon oxynitride, carbon-containing silicon oxide, aluminum oxide, another suitable material, or a combination thereof. The contact etch stop layer 139 may have a thickness that is within a range from about 4 nm to about 5 nm. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited over the structure shown in FIG. 3G. The etch stop material layer may be deposited using a CVD process, an ALD process, a PVD process, another applicable process, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3H. The planarization process may include a CMP process, a grinding process, an etching process, a dry polishing process, another applicable process, or a combination thereof.

In some embodiments, the mask layers 122 and 124 over the dummy gate stacks 120A and 120B are also removed during the planarization process. In some embodiments, after the planarization process, the top surfaces of the contact etch stop layer 139, the dielectric layer 140, and the dummy gate electrodes 118 are substantially level with each other.

As shown in FIG. 3I, the dielectric layer 140 is partially removed so that recesses 304 are formed, in accordance with some embodiments. One or more etching processes may be used to form the recesses 304. The recesses 304 may be used to contain protective elements that will subsequently be formed.

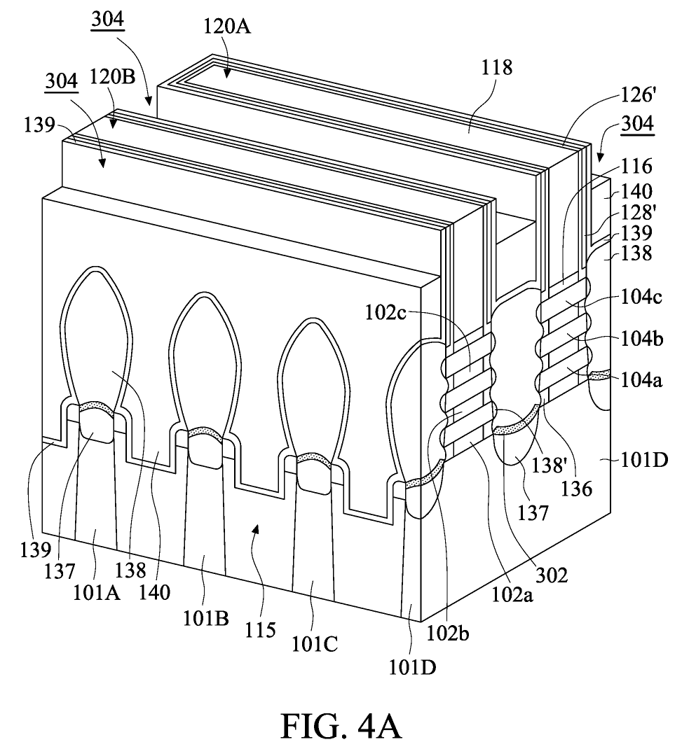

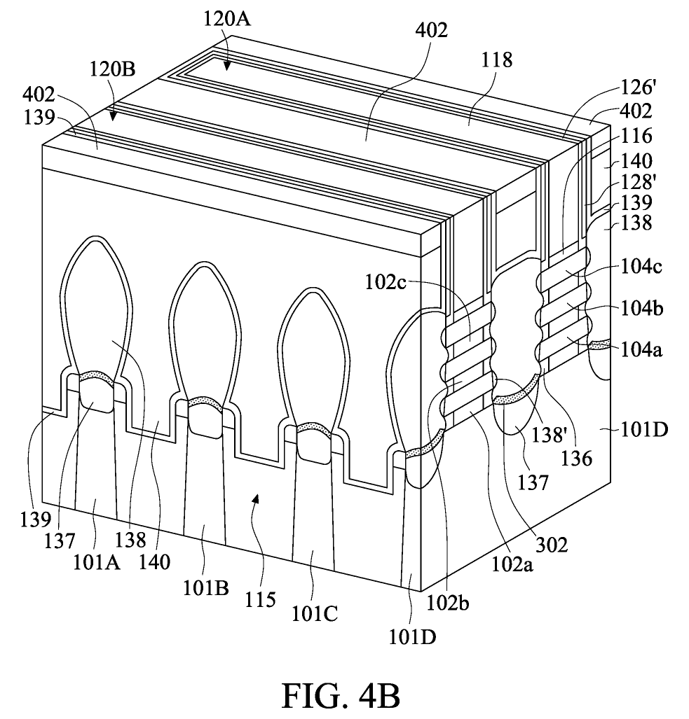

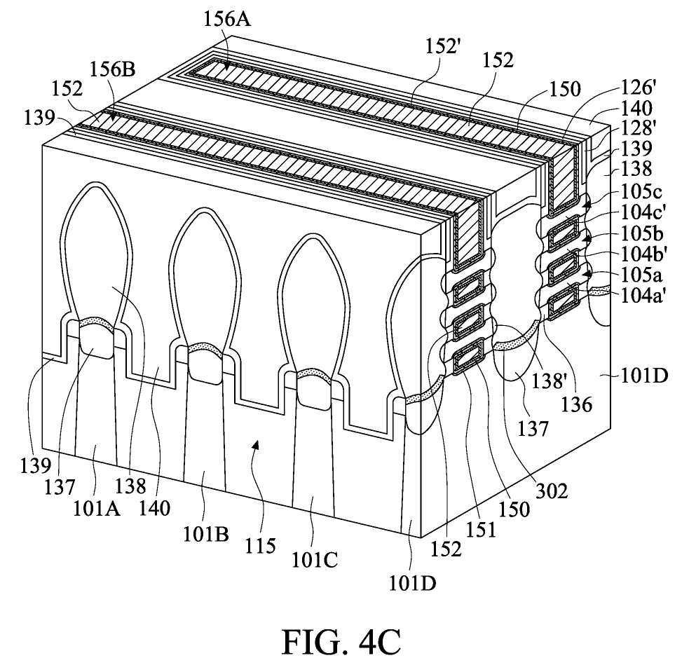

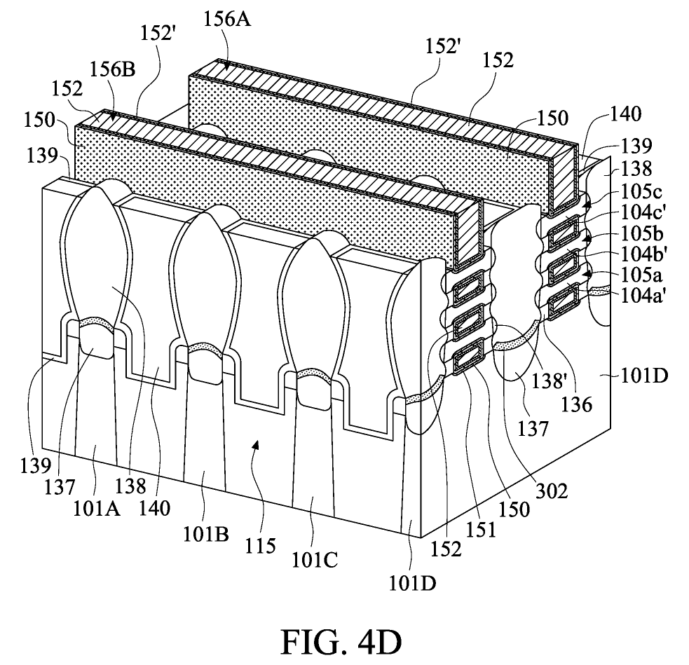

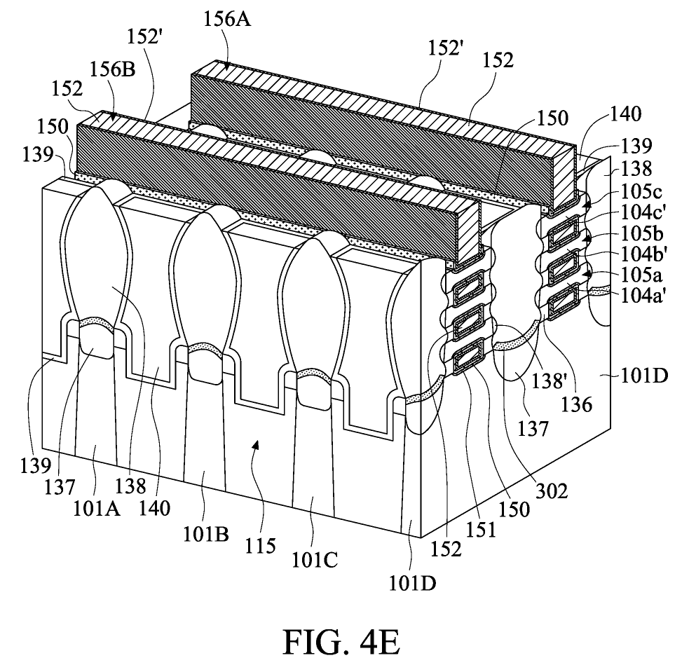

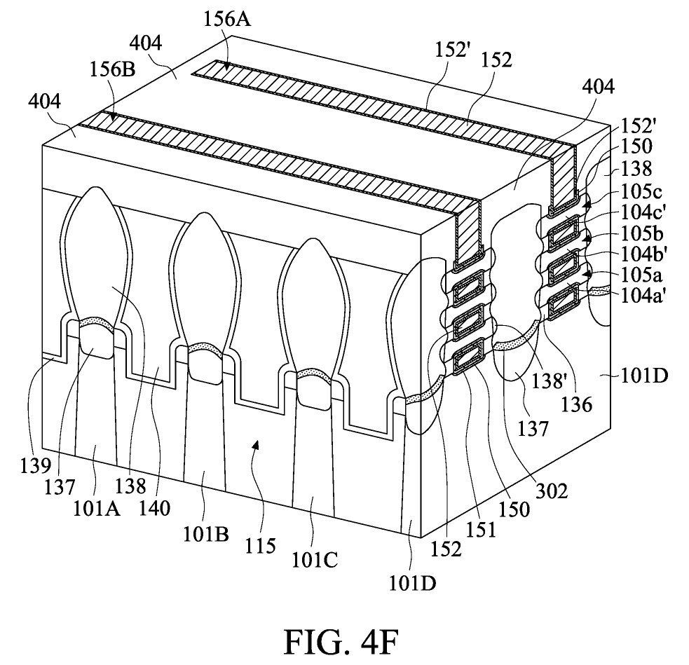

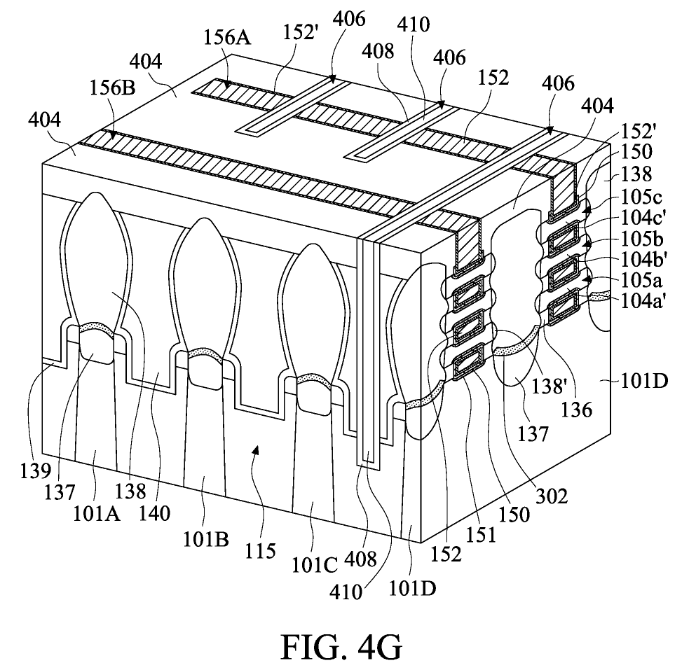

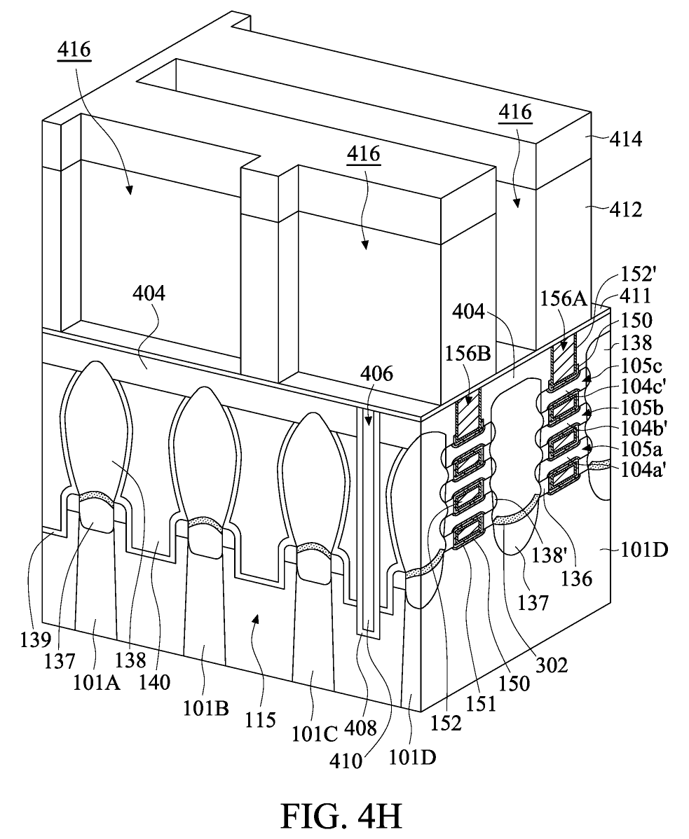

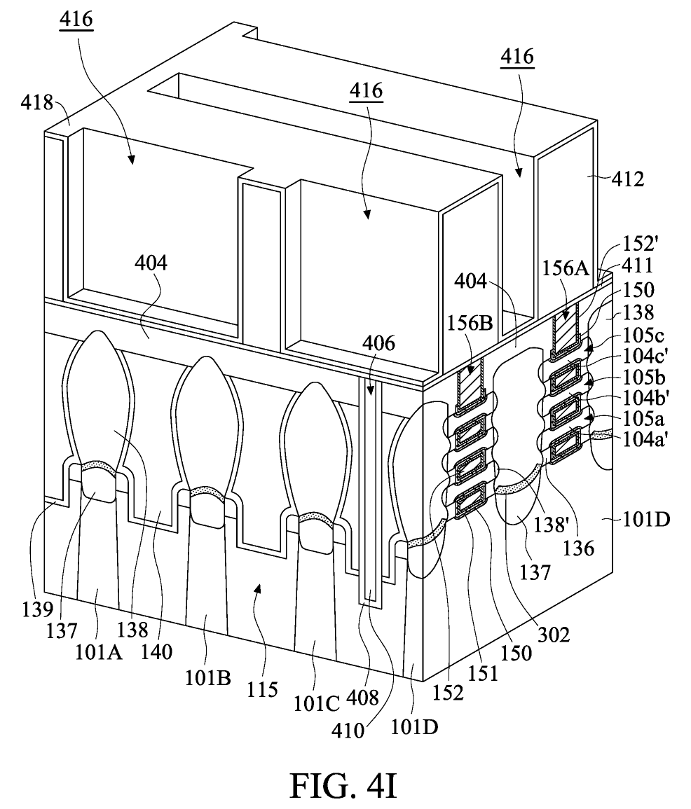

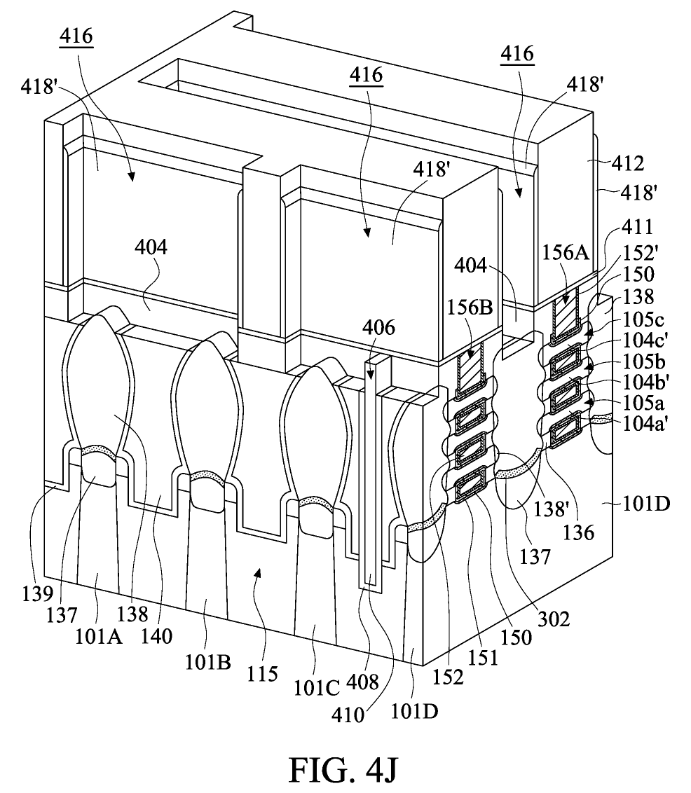

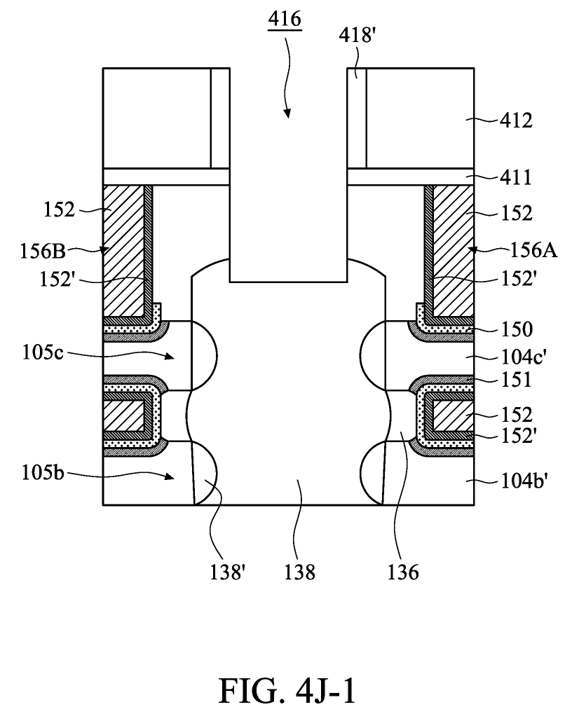

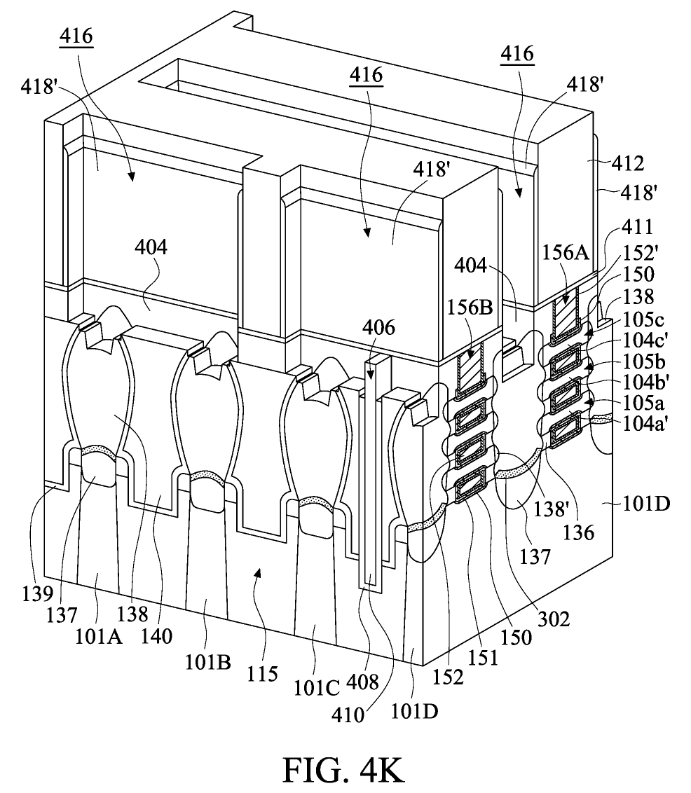

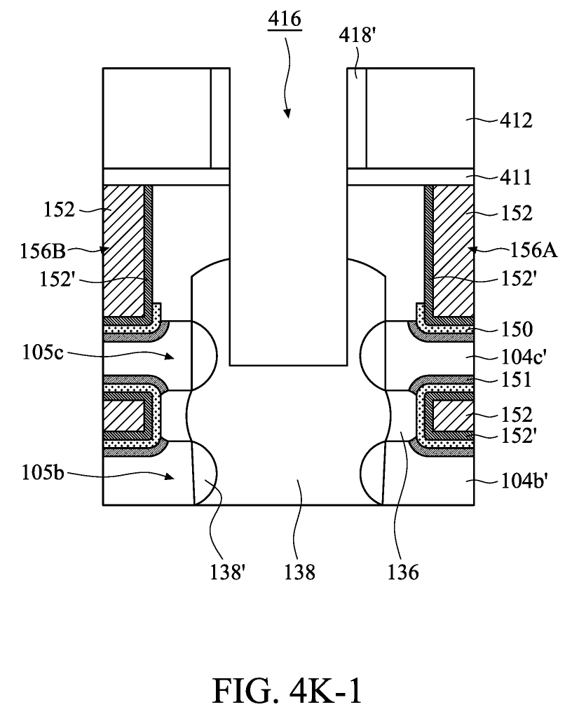

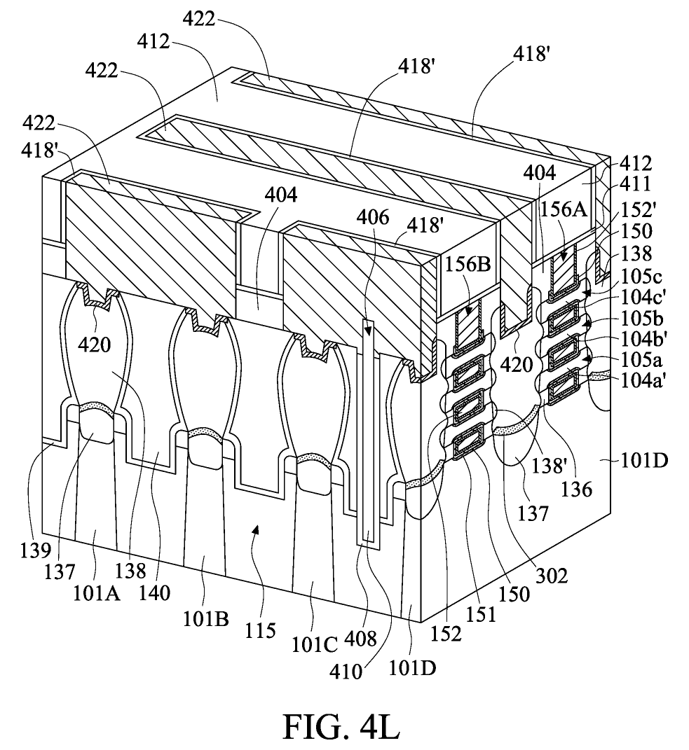

FIGS. 4A-4L are perspective views of various stages of a process for forming a portion of a semiconductor device structure, in accordance with some embodiments. The structure shown in FIG. 4A may be formed using the processes that are the same as or similar to those illustrated in FIGS. 2A-2D and 3A-3I. In some embodiments, FIG. 3I is the cross-sectional view of a portion of the structure shown in FIG. 4A.

As shown in FIG. 4B, protective caps 402 are formed in the recesses 304, in accordance with some embodiments. The protective caps 402 may protect the dielectric layer 140 underneath. In some embodiments, a protective material layer is deposited over the contact etch stop layer 139, the dummy gate stacks 120A and 120B, and the dielectric layer 140 to overfill the recesses 304. The protective material layer may be made of or include silicon nitride, silicon oxynitride, carbon-containing silicon nitride, carbon-containing silicon oxynitride, another suitable material, or a combination thereof. The protective material layer may be deposited using a CVD process, an ALD process, an FCVD process, another applicable process, or a combination thereof.

Afterwards, the protective material layer is planarized so that the dummy gate stacks 120A and 120B are exposed, in accordance with some embodiments. The remaining portions of the protective material layer form the protective caps 402, as shown in FIG. 4B. The protective material layer may be planarized using a CMP process, a grinding process, an etching process, a dry polishing process, another applicable process, or a combination thereof.

Afterwards, a gate replacement process is performed to respectively replace the dummy gate stacks 120A and 120B with metal gate stacks 156A and 156B, as shown in FIG. 4C in accordance with some embodiments. The dummy gate electrodes 118 are removed to form trenches using one or more etching processes, in accordance with some embodiments. The trenches may expose the dummy gate dielectric layer 116.

Afterwards, the dummy gate dielectric layer 116 and the semiconductor layers 102a-102c (which function as sacrificial layers) are removed, in accordance with some embodiments. In some embodiments, one or more etching processes are used to remove the dummy gate dielectric layer 116 and the semiconductor layers 102a-102c. As a result, recesses are formed between the inner spacers 136.

Due to high etching selectivity, the semiconductor layers 104a-104c are slightly (or substantially not) etched. The remaining portions of the semiconductor layers 104a-104c form multiple semiconductor nanostructures 104a’-104c’. The semiconductor nanostructures 104a’-104c’ are constructed by or made up of the remaining portions of the semiconductor layers 104a-104c. The semiconductor nanostructures 104a’-104c’ may function as channel structures of transistors.

In some embodiments, the etchant used for removing the semiconductor layers 102a-102c also slightly removes the semiconductor layers 104a-104c that form the semiconductor nanostructures 104a’-104c’. As a result, the obtained semiconductor nanostructures 104a’-104c’ become thinner after the removal of the semiconductor layers 102a-102c. In some embodiments, each of the semiconductor nanostructures 104a’-104c’ is thinner than the edge portions 105a-105c since the edge portions 105a-105c are surrounded by other elements and thus are prevented from being reached and etched by the etchant.

After the removal of the semiconductor layers 102a-102c (which function as sacrificial layers), the recesses are formed. The recesses surround each of the semiconductor nanostructures 104a’-104c’. Even if the recesses between the semiconductor nanostructures 104a’-104c’ are formed, the semiconductor nanostructures 104a’-104c’ remain held by the epitaxial structures 138. Therefore, after the removal of the semiconductor layers 102a-102c (which function as sacrificial layers), the released semiconductor nanostructures 104a’-104c’ are prevented from falling.

During the removal of the semiconductor layers 102a-102c (which function as sacrificial layers), the inner spacers 136 protect the epitaxial structures 138 from being etched or damaged. The quality and reliability of the semiconductor device structure are improved.

Afterwards, metal gate stacks 156A and 156B are formed to fill the trenches and the recesses, in accordance with some embodiments. The metal gate stacks 156A and 156B further extend into the recesses to wrap around each of the semiconductor nanostructures 104a’-104c’. Each of the metal gate stacks 156A and 156B includes multiple metal gate stack layers. Each of the metal gate stacks 156A and 156B may include interfacial layers 151, a gate dielectric layer 150, and a metal gate electrode that includes one or more work function layers 152’ and a conductive filling 152.

In some embodiments, the formation of the metal gate stacks 156A and 156B involves the deposition of multiple metal gate stack layers over the dielectric layer 140 to fill the trenches and the recesses. The metal gate stack layers extend into the recesses to wrap around each of the semiconductor nanostructures 104a’-104c’.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, another applicable process, or a combination thereof.

In some embodiments, before the formation of the gate dielectric layer 150, interfacial layers 151 are formed on the surfaces of the semiconductor nanostructures 104a’-104c’. The interfacial layers 151 are very thin and are made of, for example, silicon oxide or germanium oxide. In some embodiments, the interfacial layers 151 are formed by applying an oxidizing agent to the surfaces of the semiconductor nanostructures 104a’-104c’. For example, a hydrogen peroxide-containing liquid may be provided or applied to the surfaces of the semiconductor nanostructures 104a’-104c’ so as to form the interfacial layers 151.

The work function layer 152’ of the metal gate electrode may be used to provide the desired work function for transistors to enhance device performance including improved threshold voltage. In some embodiments, the work function layer 152’ is used for forming a PMOS device. The work function layer 152’ is a p-type work function layer. The p-type work function layer is capable of providing a work function value suitable for the device, such as equal to or greater than about 4.8 eV.

The p-type work function layer may include metal, metal carbide, metal nitride, another suitable material, or a combination thereof. For example, the p-type metal includes tantalum nitride, tungsten nitride, titanium nitride, another suitable material, or a combination thereof.

In some other embodiments, the work function layer 152’ is used for forming an NMOS device. The work function layer 152’ is an n-type work function layer. The n-type work function layer is capable of providing a work function value suitable for the device, such as equal to or less than about 4.5 eV.

The n-type work function layer may include metal, metal carbide, metal nitride, or a combination thereof. In some embodiments, the n-type work function is an aluminum-containing layer. The aluminum-containing layer may be made of or include TiAlC, TiAlO, TiAlN, another suitable material, or a combination thereof.

The work function layer 152’ may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer 152’ may be fine-tuned to adjust the work function level.

The work function layer 152’ may be deposited over the gate dielectric layer 150 using an ALD process, a CVD process, a PVD process, an electroplating process, an electrochemical plating process, another applicable process, or a combination thereof.

In some embodiments, a barrier layer is formed before the work function layer 152’ to interface the gate dielectric layer 150 with the subsequently formed work function layer. The barrier layer may also be used to prevent diffusion between the gate dielectric layer 150 and the subsequently formed work function layer 152’. The barrier layer may be made of or include a metal-containing material. The metal-containing material may include titanium nitride, tantalum nitride, another suitable material, or a combination thereof. The barrier layer may be deposited using an ALD process, a CVD process, a PVD process, an electroplating process, an electrochemical plating process, another applicable process, or a combination thereof.

In some embodiments, different portions of the metal gate stacks 156A and 156B are wrapped around semiconductor nanostructures 104a’-104c’ of different devices including PMOS devices and NMOS devices. Different portions of the metal gate stacks 156A and 156B thus have different types of work function layer or different combinations of work functions layers. Multiple deposition processes and multiple patterning processes may be used to selectively form different work function layers at different portions of the metal gate stacks 156A and 156B.

In some embodiments, the conductive fillings 152 of the metal gate electrodes are made of or include a metal material. The metal material may include tungsten, ruthenium, aluminum, copper, cobalt, another suitable material, or a combination thereof. A conductive layer used for forming the conductive filling 152 may be deposited over the work function layer 152’ using a CVD process, an ALD process, a PVD process, an electroplating process, an electrochemical plating process, a spin coating process, another applicable process, or a combination thereof.

In some embodiments, a blocking layer is formed over the work function layer 152’ before the formation of the conductive layer used for forming the conductive filling. The blocking layer may be used to prevent the subsequently formed conductive layer from diffusing or penetrating into the work function layer 152’. The blocking layer may be made of or include tantalum nitride, titanium nitride, another suitable material, or a combination thereof. The blocking layer may be deposited using an ALD process, a PVD process, an electroplating process, an electrochemical plating process, another applicable process, or a combination thereof.

Afterwards, a planarization process is performed to remove the portions of the metal gate stack layers outside of the trenches, in accordance with some embodiments. As a result, the remaining portions of the metal gate stack layers form the metal gate stacks 156A and 156B, as shown in FIG. 4C.

During the processes illustrated in FIG. 4C, multiple etching processes and one or more planarization processes are used. The protective caps 402 may prevent the dielectric layer 140 from being damaged. In some embodiments, the protective caps 402 are removed or consumed during the planarization process for forming the metal gate stacks 156A and 156B.

As shown in FIG. 4D, the dielectric layer 140, the contact etch stop layer 139, and the gate spacers 128’ and 126’ are partially removed, in accordance with some embodiments. As a result, the gate dielectric layer 150 extending along the sidewall of the upper portions of the metal gate electrodes is exposed. One or more etching processes may be used to partially remove the dielectric layer 140, the contact etch stop layer 139, and the gate spacers 128’ and 126’.

As shown in FIG. 4E, the gate dielectric layer 150 is partially removed, in accordance with some embodiments. One or more etching processes may be used to recess the gate dielectric layer 150. As a result, the sidewalls of the metal gate electrodes that are previously covered by the gate dielectric layer 150 are exposed. As shown in FIG. 4E, the work function layer 152’ is exposed. In some embodiments, each of the metal gate electrodes has a protruding portion that protrudes from the top surface of the gate dielectric layer 150, as shown in FIG. 4E. In some embodiments, the protruding portion includes a portion of the conductive filling 152 that is surrounded by the upper portion of the work function layer 152’, as shown in FIG. 4E. In some embodiments, the protruding portions of the metal gate electrodes are not laterally surrounded by the gate dielectric layer 150, the gate spacers 126’ and 128’, the contact etch stop layer 139, and the dielectric layer 140.

As shown in FIG. 4F, protective structures 404 are formed over the dielectric layer 140 and the epitaxial structures 138, in accordance with some embodiments. The protective structures 404 laterally surround the protruding portions of the metal gate electrodes. In some embodiments, the protective structures 404 are in direct contact with the metal gate electrodes, the gate dielectric layer 150, and the epitaxial structures 138. In some embodiments, the protective structures 404 are in direct contact with the work function layer 152’ and the gate dielectric layer 150, as shown in FIG. 4F.

In some embodiments, a protective material layer is deposited over the contact etch stop layer 139, the dielectric layer 140, the metal gate stacks 156A and 156B, and the epitaxial structures 138. The protective material layer may be made of or include silicon nitride, silicon oxynitride, carbon-containing silicon nitride, carbon-containing silicon oxynitride, another suitable material, or a combination thereof. The protective material layer may be deposited using a CVD process, an ALD process, an FCVD process, another applicable process, or a combination thereof.

Afterwards, the protective material layer is planarized so that the work function layer 152’ and the conductive fillings 152 of the metal gate electrodes of the metal gate stacks 156A and 156B are exposed, in accordance with some embodiments. The remaining portions of the protective material layer form the protective structures 404, as shown in FIG. 4F. The protective material layer may be planarized using a CMP process, a grinding process, an etching process, a dry polishing process, another applicable process, or a combination thereof.

As shown in FIG. 4G, multiple dielectric structures 406 are formed to separate each of the metal gate stacks 156A and 156B into two or more separate portions, in accordance with some embodiments. In some embodiments, the separate portions of the metal gate stacks 156A and 156B are physically and/or electrically isolated from each other by the dielectric structures 406. In some embodiments, the dielectric structures 406 penetrate through the protective structures 404, the metal gate stacks 156A and 156B, the dielectric layer 140, and the contact etch stop layer 139. In some embodiments, the dielectric structures 406 are in direct contact with the protective structures 404 and the metal gate stacks 156A and 156B. In some embodiments, the dielectric structures 406 are in direct contact with the work function layers 152’ and the conductive fillings 152 of the metal gate stacks 156A and 156B.

In some embodiments, each of the dielectric structures 406 includes a protective liner layer 408 and a dielectric filling 410, as shown in FIG. 4G. The protective liner layer 408 may be made of a dielectric layer that is substantially free of oxygen. The protective liner layer 408 may be made of or include silicon nitride, carbon-containing silicon nitride, another suitable material, or a combination thereof. In some embodiments, the dielectric filling 410 has a lower dielectric constant than that of the protective liner layer 408. The dielectric filling 410 may be made of or include silicon oxide, silicon oxynitride, carbon-containing silicon oxide, carbon-containing silicon oxynitride, another suitable material, or a combination thereof. The protective liner layer 408 may help to prevent oxygen of the dielectric filling 410 from diffusing into the metal gate stacks 156A and 156B that are nearby. The quality and reliability of the metal gate stacks 156A and 156B may thus be ensured.

In some embodiments, one or more photolithography processes and one or more etching processes are used to form multiple trenches that are used to contain the dielectric structures 406. Afterwards, a liner material layer and a dielectric material layer are sequentially deposited to overfill the trenches. A planarization process is then used to partially remove the liner material layer and the dielectric material layer. As a result, remaining portions of the liner material layer and the dielectric material layer respectively form the protective liner layers 408 and the dielectric fillings 410 of the dielectric structures 406. The planarization process may include a CMP process, a grinding process, an etching process, a dry polishing process, another applicable process, or a combination thereof.

In some embodiments, due to the planarization process, the top surfaces of the dielectric structures 406, the metal gate stacks 156A and 156B, the contact etch stop layer 139, and the protective structures 404 are substantially level, as shown in FIG. 4G. In some embodiments, the bottoms of the protective structures 404 are vertically positioned between the tops and bottoms of the epitaxial structures 138.

As shown in FIG. 4H, an etch stop layer 411, a dielectric layer 412, and a mask element 414 are sequentially formed over the structure shown in FIG. 4G, in accordance with some embodiments. The material and formation method of the etch stop layer 411 may be the same as or similar to those of the contact etch stop layer 139. The material and formation method of the dielectric layer 412 may be the same as or similar to those of the dielectric layer 140. The mask element 414 may be made of or include tungsten carbide or another suitable material. The etch stop layer 411, the dielectric layer 412, and the mask element 414 may be formed using a CVD process, an ALD process, another applicable process, or a combination thereof. One or more photolithography processes and one or more etching processes may be used to pattern the mask element 414. As a result, multiple openings are formed in the mask element 414.

Afterwards, with the mask element 414 as an etching mask, the dielectric layer 412 is partially removed, in accordance with some embodiments. As a result, multiple contact openings 416 are formed. The position and profile of the contact openings 416 may be the same as or similar to those of the mask element 414. The contact openings 416 expose the etch stop layer 411 over the protective structures 404. One or more etching processes may be used to form the contact openings 416. As shown in FIG. 4H, the protective structures 404 may also protect the dielectric layer 140 underneath during the formation of the contact openings 416.

In some embodiments, an over etching process is used to ensure that the contact openings 416 completely penetrate through the dielectric layer 412. The etch stop layer 411 may thus be partially removed during the over etching process. As a result, the protective structures 404 are exposed by the contact openings 416. In some embodiments, the protective structures 404 are also partially removed during the over etching process. In some embodiments, due to the over etching process, the protective structures 404 thus have curved upper surfaces.

As shown in FIG. 4I, a protective material layer 418 is formed over the dielectric layer 412, in accordance with some embodiments. The protective material layer 418 extends along the sidewalls and bottoms of the contact openings 416. The protective material layer 418 may be used to protective the dielectric layer 412 during the subsequent processes. Each of the protective material layer 418 may have a thickness that is within a range from about 1 nm to about 3 nm.

In some embodiments, the protective material layer 418 is substantially free of oxygen. The protective material layer 418 may be made of or include silicon nitride, carbon-containing silicon nitride, another suitable material, or a combination thereof. However, embodiments of the disclosure have many variations. In some other embodiments, the protective material layer 418 contain oxygen. For example, the protective material layer 418 are made of or include silicon oxynitride, carbon-containing silicon oxynitride, another suitable material, or a combination thereof. In some embodiments, the protective material layer 418 is deposited using a CVD process, an ALD process, another applicable process, or a combination thereof.

FIGS. 4J-1 and 4K-1 are cross-sectional views of various stages of a process for forming a portion of a semiconductor device structure, in accordance with some embodiments. In some embodiments, FIG. 4J-1 is the cross-sectional view of a portion of the structure shown in FIG. 4J. In some embodiments, FIG. 4K-1 is the cross-sectional view of a portion of the structure that will be illustrated in FIG. 4K later.

As shown in FIGS. 4J and 4J-1, an anisotropic etching process is used to remove the portions of the protective material layer 418 at the bottoms of the contact openings 416. As a result, the remaining portions of the protective material layer 418 form multiple protective layers 418’. The protective layers 418’ are separated from the epitaxial structures 138 by the protective structures 404.

In some embodiments, the anisotropic etching process also partially remove the protective structures 404 so that the contact openings 416 become deeper. In some embodiments, the contact openings 416 expose the epitaxial structures 138. In some embodiments, the contact openings 416 slightly extend into the epitaxial structures 138, as shown in FIGS. 4J and 4J-1.

As shown in FIGS. 4K and 4K-1, the epitaxial structures 138 are partially removed, in accordance with some embodiments. As a result, the contact openings 416 are deepened. The contact openings 416 further extend into the epitaxial structures 138. The contact openings 416 expose interior sidewalls of the epitaxial structures 138, as shown in FIGS. 4K and 4K-1. In some embodiments, the protective layers 418’ are formed before the contact openings 416 are deepened. The protective layers 418’ are prevented from extending along the interior sidewalls of the epitaxial structures 138.

Afterwards, a cleaning operation is performed to clean the exposed surfaces of the epitaxial structures 138 before a subsequent formation of metal-semiconductor compound elements on the epitaxial structures 138. During the cleaning operation, the protective layers 418’ may prevent the dielectric layer 412 from being damaged by the chemicals used in the cleaning operation. The position and profile of the contact openings 416 may thus be maintained, which facilitate the subsequent formation of conductive contacts in the contact openings 416.

As shown in FIG. 4L, metal-semiconductor compound elements 420 are formed on the surfaces of the epitaxial structures 138 that are exposed by the contact openings 416, in accordance with some embodiments. In some embodiments, the metal-semiconductor compound elements 420 are embedded in the epitaxial structures 138. The metal-semiconductor compound elements 420 may improve the electrical connection between the epitaxial structures 138 and conductive contacts that will be formed on the metal-semiconductor compound elements 420. Each of the metal-semiconductor compound elements 420 may have a thickness that is within a range from about 2 nm to about 6 nm. Each of the metal-semiconductor compound elements 420 may have a length that is within a range from about 20 nm to about 35 nm.

In some embodiments, before the formation of the metal-semiconductor compound elements 420, the exposed epitaxial structures 138 are modified to assist in the subsequent formation of the metal-semiconductor compound elements 420. In some embodiments, one or more ion implantation processes are used to reduce the crystallinity of the surface portions of the epitaxial structures 138, which allows a subsequently deposited metal material to react with the modified surface portions more easily. The formation of the metal-semiconductor compound elements 420 may thus be facilitated.

In some embodiments, the implantation process is a plasma doping process. Plasma may be introduced into the contact openings 416 to modify the exposed surface portions of the epitaxial structures 138. In some embodiments, reaction gas used in the implantation process includes silicon-containing gas, germanium-containing gas, argon-containing gas, helium-containing gas, another suitable gas, or a combination thereof.

In some embodiments, a thermal operation is performed after a metal-containing material is applied to (or deposited on) the epitaxial structures 138. In some other embodiments, a metal-containing material is applied to (or deposited on) the epitaxial structures 138 while the epitaxial structures 138 is heated, in accordance with some embodiments. In some embodiments, the metal-containing material is applied (or deposited) using a CVD process, an ALD process, or a combination thereof.

Due to the thermal operation, the thermal energy may help to initiate chemical reaction between the surface portions of the epitaxial structures 138 and the metal-containing material. As a result, the surface portions of the epitaxial structures 138 react with the metal-containing material, and they are transformed into the metal-semiconductor compound elements 420.

The metal-semiconductor compound elements 420 may be made of or include a metal silicide material, a silicon-germanium-metal-containing material, a germanium-metal-containing material, another suitable material, or a combination thereof. For example, the metal-semiconductor compound elements 420 include TiSi, MoSi, RuSi, ZrSi, another suitable material, or a combination thereof.

In some embodiments, during the thermal operation, the epitaxial structures 138 are heated to a temperature that is in a range from about 390 degrees C to about 440 degrees C. In some other embodiments, before the metal-containing material is applied to (or deposited on) the epitaxial structures 138, the epitaxial structures 138 are heated to be at a raised temperature. Afterwards, the epitaxial structures 138 are kept at the raised temperature while the metal-containing material is applied (or deposited). The raised temperature may be in a range from about 390 degrees C to about 440 degrees C.

In some embodiments, while applying or depositing the metal-containing material for forming the metal-semiconductor compound elements 420, the metal-containing material is also applied to (or deposited on) sidewalls and bottom surfaces of the contact openings 416 to form metal layers. The metal layers may be made of or include titanium, cobalt, ruthenium, molybdenum, nickel, tantalum, tungsten, platinum, another suitable material, or a combination thereof. In some embodiments, after the formation of the metal-semiconductor compound elements 420, the portions of the metal layers that are not react with the epitaxial structures 138 are removed. One or more etching processes may be used to remove the metal layers. The protective layers 418’ may protect the dielectric layer 412 during the etching processes.

However, embodiments of the disclosure are not limited thereto. Many variations and/or modifications can be made to embodiments of the disclosure. In some other embodiments, the metal-semiconductor compound elements 420 are not formed.

As shown in FIG. 4L, conductive contacts 422 are formed in the contact openings 416, in accordance with some embodiments. In some embodiments, the conductive contacts 422 completely fill the remaining portions of the contact openings 416, as shown in FIG. 4L. In some embodiments, the conductive contacts 422 penetrate through the dielectric layer 412 and the protective structures 404. In some embodiments, the bottoms of the conductive contacts 422 are below the topmost surfaces of the semiconductor nanostructures 104c’, as shown in FIG. 4L.

In some embodiments, the protective layers 418’ are formed before the formation of the metal-semiconductor compound elements 420 and the conductive contacts 422. In some embodiments, due to the protective structures 404, the protective layers 418’ are prevented from reaching the epitaxial structures 138. The protective layers 418’ have no portion that is positioned between the conductive contacts 422 and the epitaxial structures 138. The electrical connection between the conductive contacts 422 and the epitaxial structures 138 is thus significantly improved.

In some embodiments, a conductive material layer is deposited over the dielectric layer 412, the protective structures 404, and the metal-semiconductor compound elements 420 to overfill the contact openings 416. The conductive material layer may be made of or include tungsten, ruthenium, molybdenum, cobalt, titanium, tantalum, tungsten, another suitable material, or a combination thereof. The conductive material layer may be deposited using an ALD process, a CVD process, a PVD process, an electroplating process, an electrochemical plating process, another applicable process, or a combination thereof.

Afterwards, a planarization process is used to remove the conductive material layer outside of the contact openings 416, in accordance with some embodiments. As a result, the remaining portions of the conductive material layer in the contact openings 416 form the conductive contacts 422, as shown in FIG. 4L. The planarization process mentioned above may include a CMP process, a grinding process, an etching process, a dry polishing process, another applicable process, or a combination thereof. During the planarization process, the dielectric layer 412 and the protective layers 418’ may also be partially removed.

Afterwards, one or more dielectric layers and one or more conductive features may be formed over the structure shown in FIG. 4L.

In some embodiments, the protective structures 404 protect the dielectric layer 140 underneath during the formation of the conductive contacts 422. The portions of the conductive contacts 422 that extend into the dielectric layer 140 may thus be restricted to a limited amount. The overlapping area between the nearby conductive contacts 422 may thus be reduced, which may help to reduce the parasitic capacitance. The operation speed and quality of the semiconductor device structure may be improved.

In some embodiments, each of the conductive contacts 422 has a portion that is laterally surrounded by the protective structures 404 and the dielectric layer 140. The portion of the conductive contact 422 may have a thickness that is within a range from about 15 nm to about 65 nm.

As shown in FIG. 4L, the gate dielectric layer 150 that has a high dielectric constant does not laterally surround the upper portions of the metal gate electrodes. The parasitic capacitance between the metal gate electrodes and the conductive contacts 422 may thus be reduced. The operation speed and quality of the semiconductor device structure may be improved.

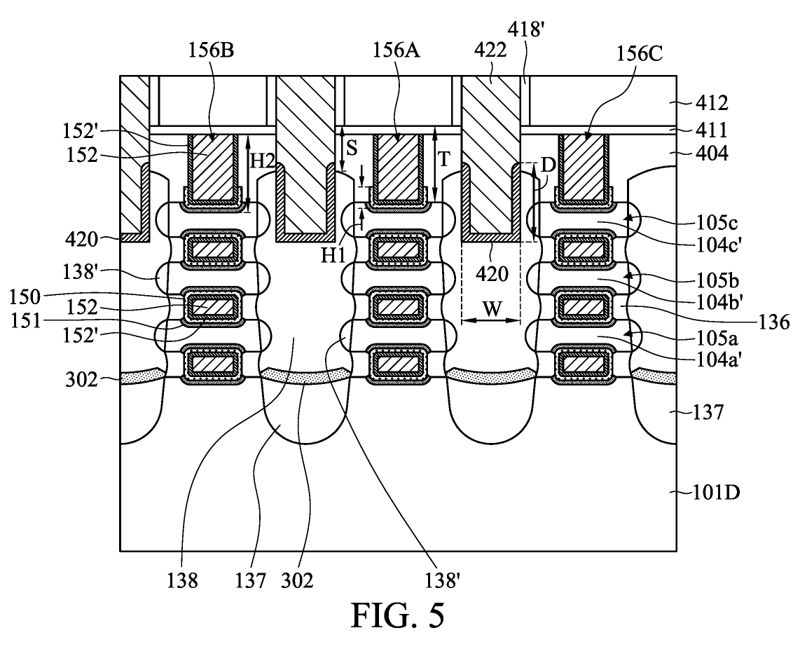

FIG. 5 is a cross-sectional view of a stage of a process for forming a portion of a semiconductor device structure, in accordance with some embodiments. In some embodiments, FIG. 5 is a cross-sectional view of a structure that is the same as or similar to the structure shown in FIG. 4L. A metal gate stack 156C is also shown in FIG. 5.

In some embodiments, the protective layers 418’ are separated from the epitaxial structures 138 without being laterally surrounded by the epitaxial structures 138, as shown in FIGS. 4L and 5. As shown in FIG. 5, each of the protective layers 418’ is separated from the epitaxial structure 138 thereunder by a distance S. The distance S may be within a range from about 2 nm to about 8 nm. In some embodiments, each of the protective layers 418’ is in direct contact with the respective protective structures 404 that is nearby. In some embodiments, each of the metal-semiconductor compound elements 420 has a length that is within a range from about 20 nm to about 35 nm.

As shown in FIG. 5, each of the conductive contacts 422 has an embedded portion that is laterally surrounded by the respective epitaxial structure 138. As shown in FIG. 5, the embedded portion has a depth D that may be within a range from about 1 nm to about 45 nm. In some other embodiments, the conductive contacts 422 do not extend into the epitaxial structures 138. As shown in FIG. 5, the embedded portion has a width W that may be within a range from about 10 nm to about 16 nm.

As shown in FIG. 5, the gate dielectric layer 150 has a height H1 measured from the top of the gate dielectric layer 150 to the top of the topmost semiconductor nanostructure such as the semiconductor nanostructure 104c’. The height H1 may be within a range from about 2 nm to about 8 nm.

As shown in FIG. 5, each of the metal gate stacks 156A-156C has a height H2 measured from the tops of the metal gate stacks 156A-156C to the top of the topmost semiconductor nanostructure such as the semiconductor nanostructure 104c’. The height H2 may be within a range from about 10 nm to about 20 nm. As shown in FIG. 5, each of the protective structures 404 has a thickness T. The thickness T may be within a range from about 5 nm to about 14 nm.

The dielectric layer 412 has a thickness that may be within a range from about 10 nm to about 20 nm. Each of the dielectric structures 406 has a width that may be within a range from about 21 nm to about 33 nm. Each of the dielectric structures 406 has a depth that may be within a range from about 110 nm to about 160 nm.

Many variations and/or modifications can be made to embodiments of the disclosure. In some embodiments, there are fin bottom isolation structures formed between the semiconductor fin and the semiconductor substrate 100. The fin bottom isolation structures may be made of or include silicon nitride, carbon-containing silicon oxynitride, carbon-containing silicon nitride, carbon-containing silicon oxide, silicon oxide, another suitable material, or a combination thereof. Each of the fin bottom isolation structures may have a thickness that is within a range from about 2 nm to about 6 nm.

Many variations and/or modifications can be made to embodiments of the disclosure. In some embodiments, there are three channel structures (such as the semiconductor nanostructures 104a’-104c’) formed between the nearby epitaxial structures 138. However, embodiments of the disclosure are not limited thereto. Many variations and/or modifications can be made to embodiments of the disclosure. In some embodiments, the total number of semiconductor nanostructures between the nearby epitaxial structures 138 is greater than three. In some other embodiments, the total number of semiconductor nanostructures between the nearby epitaxial structures 138 is smaller than three. The total number of semiconductor nanostructures (or channel structures) between the nearby epitaxial structures 138 may be fine-tuned to meet requirements. For example, the total number of semiconductor nanostructures between the nearby epitaxial structures 138 may be between 2 and 10. The semiconductor nanostructures may have many applicable profiles. The semiconductor nanostructures may include nanosheets, nanowires, or other suitable nanostructures.

Embodiments of the disclosure replace the dielectric elements (including a high-k gate dielectric layer) surrounding an upper portion of a metal gate electrode with a protective structure. The parasitic capacitance between the metal gate electrode and a conductive contact may thus be reduced. A protective layer is formed between the conductive contact and a dielectric layer laterally surrounding the conductive contact. The conductive contact further extends into the epitaxial structure so as to increase the contact area and to reduce the resistance between the conductive contact and the epitaxial structure. The protective layer is blocked by the protective structure. The protective layer is thus prevented from reaching the interior sidewalls of the epitaxial structure and separating the conductive contact from the epitaxial structure. The contact area between the conductive contact and the epitaxial structure may thus remain large. The performance and reliability of the semiconductor device structure are thus improved.

In accordance with some embodiments, a method for forming a semiconductor device structure is provided. The method includes forming a metal gate stack wrapped around multiple semiconductor nanostructures. The metal gate stack has a gate dielectric layer and a gate electrode, and the semiconductor nanostructures are adjacent to an epitaxial structure. The method also includes recessing the gate dielectric layer, and a protruding portion of the gate electrode protrudes from a top surface of the gate dielectric layer after the gate dielectric layer is recessed. The method further includes forming a protective structure over the epitaxial structure, and the protective structure laterally surrounds the protruding portion of the gate electrode. In addition, the method includes forming a conductive contact electrically connected to the epitaxial structure and penetrating through the protective structure.

In accordance with some embodiments, a method for forming a semiconductor device structure is provided. The method includes forming a metal gate stack extending across a semiconductor nanostructure. The metal gate stack has a gate dielectric layer and a gate electrode, and the semiconductor nanostructure is electrically connected to an epitaxial structure. The method also includes partially removing the gate dielectric layer so that a sidewall of the gate electrode previously covered by the gate dielectric layer is exposed. The method further includes forming a protective structure laterally surrounding the sidewall of the gate electrode. In addition, the method includes forming a conductive contact electrically connected to the epitaxial structure and penetrating through the protective structure.

In accordance with some embodiments, a semiconductor device structure is provided. The semiconductor device structure includes an epitaxial structure and a semiconductor nanostructure electrically connected to the epitaxial structure. The semiconductor device structure also includes a metal gate stack extending across the semiconductor nanostructure, and the metal gate stack has a gate dielectric layer and a gate electrode. The semiconductor device structure further includes a protective structure over the metal gate stack and the epitaxial structure. A top of the gate dielectric layer is between a top surface of the protective structure and a bottom surface of the protective structure. The top of the gate dielectric layer is closer to the semiconductor nanostructure than a top of the metal gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
an epitaxial structure;
a semiconductor nanostructure beside the epitaxial structure;
a metal gate stack at least partially wrapped around the semiconductor nanostructure, wherein the metal gate stack has a gate dielectric layer and a gate electrode, and a topmost surface of the gate dielectric layer is closer to the semiconductor nanostructure than a top of the gate electrode; and
a protective structure laterally surrounding an upper portion of the metal gate stack and at least partially covering the epitaxial structure, wherein a bottom surface of the protective structure is vertically located between a top of the epitaxial structure and a bottom of the epitaxial structure.

2. The semiconductor device structure as claimed in claim 1, further comprising:
a conductive contact electrically connected to the epitaxial structure, wherein the protective structure laterally surrounds a portion of the conductive contact.

3. The semiconductor device structure as claimed in claim 2, wherein the conductive contact extends into the epitaxial structure and vertically extends past a topmost surface of the semiconductor nanostructure.

4. The semiconductor device structure as claimed in claim 3, further comprising:
a metal-semiconductor compound element between the epitaxial structure and the conductive contact.

5. The semiconductor device structure as claimed in claim 2, further comprising:
a dielectric layer laterally surrounding an upper portion of the conductive contact; and
a protective layer between the conductive contact and the dielectric layer, wherein the protective layer is separated from the epitaxial structure by the protective structure.

6. The semiconductor device structure as claimed in claim 2, further comprising:
a dielectric structure extending downward into the metal gate stack and the protective structure.

7. The semiconductor device structure as claimed in claim 2, wherein the conductive contact vertically extends past a topmost surface of the protective structure and a bottommost surface of the protective structure.

8. The semiconductor device structure as claimed in claim 1, wherein the protective structure laterally extends past opposite edges of the epitaxial structure.

9. The semiconductor device structure as claimed in claim 1, wherein a portion of the protective structure is laterally located between the epitaxial structure and the metal gate stack.

10. A semiconductor device structure, comprising:
an epitaxial structure;
a plurality of semiconductor nanostructures beside the epitaxial structure;
a metal gate stack wrapped around the semiconductor nanostructures, wherein the metal gate stack has a gate dielectric layer, a work function layer, and a conductive filling;
a protective structure over the metal gate stack and the epitaxial structure, wherein a topmost surface of the work function layer is closer to a top of the protective structure than the gate dielectric layer; and
a conductive contact electrically connected to the epitaxial structure, wherein the conductive contact vertically extends past opposite surfaces of the protective structure.

11. The semiconductor device structure as claimed in claim 10, wherein a lower portion of the protective structure is laterally located between the epitaxial structure and the gate dielectric layer.

12. The semiconductor device structure as claimed in claim 10, wherein the epitaxial structure extends upward past an interface between the protective structure and one of the semiconductor nanostructures.

13. The semiconductor device structure as claimed in claim 10, wherein a topmost surface of the gate dielectric layer is vertically located between a bottommost surface of the protective structure and the topmost surface of the work function layer.

14. The semiconductor device structure as claimed in claim 10, further comprising:
a metal-semiconductor compound layer between the conductive contact and the epitaxial structure, wherein the metal-semiconductor compound layer vertically extends past a topmost surface of the gate dielectric layer.

15. The semiconductor device structure as claimed in claim 10, wherein the protective structure is wider than the epitaxial structure.

16. A semiconductor device structure, comprising:
an epitaxial structure;
a channel structure beside the epitaxial structure;
a metal gate stack over the channel structure, wherein the metal gate stack has a gate dielectric layer and a gate electrode, and topmost surfaces of the gate dielectric layer and the gate electrode are located at different height levels; and
a protective structure over the metal gate stack and the epitaxial structure, wherein a top of the epitaxial structure is closer to a top of the protective structure than a bottom of the protective structure.

17. The semiconductor device structure as claimed in claim 16, further comprising:
a conductive contact electrically connected to the epitaxial structure;
a metal-semiconductor compound layer laterally surrounds a lower portion of the conductive contact; and
a protective layer laterally surrounds an upper portion of the conductive contact, wherein the protective layer is spaced apart from the metal-semiconductor compound layer.

18. The semiconductor device structure as claimed in claim 17, wherein the protective structure laterally surrounds an intermediate portion of the conductive contact.

19. The semiconductor device structure as claimed in claim 18, wherein the protective structure is in direct contact with the intermediate portion of the conductive contact.

20. The semiconductor device structure as claimed in claim 16, wherein the protective structure is in direct contact with a sidewall of the gate dielectric layer and a sidewall of the gate electrode.
